(19) United States
(12) Patent Application Publication
(10) Pub. No.: US 2010/0246138 A1
(43) Pub. Date: Sep. 30, 2010

(54) METHOD, APPARATUS, AND SYSTEM FOR THIN DIE THIN THERMAL INTERFACE MATERIAL IN INTEGRATED CIRCUIT PACKAGES

(76) Inventors: Wei Shi, Gilbert, AZ (US); Daoqiang Lu, Chandler, AZ (US); Edward A. Zarbock, Gilbert, AZ (US)

Correspondence Address: SCHWEGMAN, LUNDBERG & WOESSNER, P.A., P.O. BOX 2938, MINNEAPOLIS, MN, 55402, US

(21) Appl. No.: 12/813,277

(22) Filed: Jun. 10, 2010

Related U.S. Application Data
(62) Division of application No. 11/423,551, filed on Jun. 12, 2006.

(51) Int. Cl. H05K 7/20

(52) U.S. Cl. 361/717

(57) ABSTRACT

Some embodiments of the invention include a thermal interface between a heat spreader and a die. The thermal interface may include a main layer of a single material or a combination of multiple materials. The thermal interface may include one or more additional layers covering one or more surfaces of the main layer. The thermal interface may be bonded to the die and the heat spreader at a low temperature, with flux or without flux. Other embodiments are described and claimed.

### RELATED APPLICATION

This application is a divisional of U.S. patent application Ser. No. 11/423,551, filed Jun. 12, 2006, which is incorporated herein by reference in its entirety.

### FIELD

Embodiments of the present invention relate generally to integrated circuit packaging, and particularly to an interface between a die and a heat spreader in integrated circuit packages.

### BACKGROUND

Computers and other electronic devices usually have a semiconductor die enclosed in an integrated circuit package. The die often has an integrated circuit for performing an electrical function. The integrated circuit generates heat when it operates. Excessive heat may destroy the integrated circuit. To dissipate the heat, the die is commonly attached or bonded to a heat spreader through a thermal interface material.

For improved performance, reliability, and longevity of the integrated circuit, bonding the die to the heat spreader may involve the following factors: low coefficient of thermal expansion (CTE) mismatch between the heat spreader and the die, high bond quality, low thermal resistance of the integrated circuit, ease of handling of the thermal interface material, compatibility with existing processes, and low cost.

In some integrated circuit packages, satisfying most or all of the above factors may be difficult.

### BRIEF DESCRIPTION OF DRAWINGS

FIG. 1 shows an exploded view of an apparatus before it is assembled according to an embodiment of the invention.

FIG. 2 shows an apparatus according to an embodiment of the invention.

FIG. 3 is a flowchart showing a method according to an embodiment of the invention.

FIG. 4 shows a computer system according to an embodiment of the invention.

### DESCRIPTION OF EMBODIMENTS

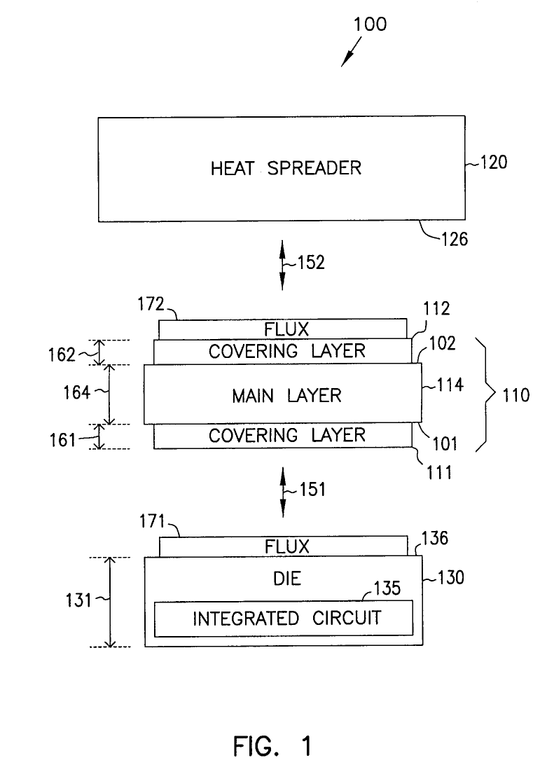

FIG. 1 shows an exploded view of an apparatus 100 before it is assembled according to an embodiment of the invention. Apparatus 100 may be a portion of an integrated circuit package that resides in computers or other electronic systems such as cellular phones. In FIG. 1, apparatus 100 includes a thermal interface 110 placed between a heat spreader 120 and a die 130. The components of apparatus 100 may be assembled or bonded together in directions indicated by arrows 151 and 152. In some embodiments, the components of apparatus 100 may be assembled in a specific process order to improve alignments among thermal interface 110, the die 130, and the heat spreader 120. For example, the specific process order may include placing thermal interface 110 over die 130 before placing heat spreader 120 over both thermal interface 110 and die 130. Further, in some embodiments, the components of apparatus 100 may be assembled in a process order such that the process order is compatible with existing high-volume-manufacturing (HVM) processes so that some or all of the existing equipment may be used to assemble apparatus 100. Therefore, a large amount of new equipment may be avoided.

Heat spreader 120 may include a copper layer or a copper layer with one or more layers of other metals covering at least a portion of a surface 126 of heat spreader 120. Die 130 includes a semiconductor material in which an integrated circuit 135 is formed. Integrated circuit 135 may have circuitry to perform a function such as processing data, or storing data, or both. Die 130 has a surface 136. At least a portion of surface 136 may be covered with one or more layers of material (e.g., one or more layers of metals). As shown in FIG. 1, die 130 has a thickness 131. In some embodiments, thickness 131 may be about 50 μm (micrometer). In other embodiments, thickness 131 may be about 300 μm. In some other embodiments, thickness 131 may be between about 50 μm and about 300 μm. In further embodiments, thickness 131 may be less than 50 μm. Thermal interface 110, when bonded to die 130 and heat spreader 120, allows some amount of heat from die 130 to dissipate or spread to heat spreader 120 to maintain proper thermal condition for apparatus 100.

Thermal interface 110 includes a main layer 114 having surfaces 101 and 102, a covering layer 111 on surface 101 of main layer 114, and a covering layer 112 on surface 102 of main layer 114. FIG. 1 shows an example where covering layer 111 covers only a portion of surface 101 and covering layer 112 covers only a portion of surface 102. In some embodiments, covering layer 111 may cover the entire surface 101; covering layer 112 may cover the entire surface 102.

Covering layers 111 and 112 may serve one or more of the following functions: reducing or preventing oxidation to surfaces 101 and 102 of main layer 114 to enhance wetting to improve bond quality between heat spreader 120 and die 130; improving the handing of thermal interface 110; and enabling bonding of thermal interface 110 to heat spreader 120 and die 130 at different process temperatures.

Covering layers 111 and 112 may have an identical material or different materials. Covering layer 111, covering layer 112, and main layer 114 may all have different materials. For example, covering layer 111 may have a first material, covering layer 112 may have a second material, and main layer 114 may have a third material.

Each of the covering layers 111 and 112 may include only a single material or a combination of multiple materials. Main layer 114 may include only a single material or combination of multiple materials. The combination of multiple materials described herein may include only two materials or more than two materials. The combination of the multiple materials may be an alloy. In some embodiments, the alloy may be a eutectic alloy.

In some embodiments, the materials for each of the main layer 114, covering layer 111, and covering layer 112 may include indium, gold, silver, and tin. In other embodiments, the materials for main layer 114, covering layer 111, and covering layer 112 include other materials. In embodiments where main layer 114 includes only two materials, the materials may be indium and silver. The indium to silver weight ratio may be about 97% indium to about 3% silver (97In3Ag). In some embodiments, the indium to silver weight ratio may be different from about 97% indium to about 3% silver.

As shown in FIG. 1, covering layer 111 has a thickness 161; covering layer 112 has a thickness 162. The values of thickness 161 and thickness 162 may be identical or different from each other. In some embodiments, each of the thickness 161 and thickness 162 may be about 0.1 μm. In other embodiments, each of the thickness 161 and thickness 162 may be about 0.5 μm. In some other embodiments, each of the thickness 161 and thickness 162 may be between about 0.1 μm and about 0.5 μm. Main layer 114 has a thickness 164. In some embodiments, thickness 164 may be about 50 μm. In other embodiments, thickness 164 may be about 100 μm. In some other embodiments, thickness 164 may be between about 50 μm and about 100 μm. The thickness values for each of the main layer 114, covering layer 111, and covering layer 112 may be at some thickness values different from the thickness values described herein.

As described above, thermal interface 110 may have different combinations of materials and a range of thickness values. Therefore, in some embodiments, by choosing the materials and the thickness for thermal interface 110 according to the materials and thickness described herein, the handling of thermal interface 110 before bonding may be improved. Further, in some embodiments, by selecting the materials and the thickness for thermal interface 110 combined with a process order, such as the process order mentioned above, thermal interface 110 may provide a high bond quality after bonding such that separation between thermal interface 110 and die 130 or between thermal interface 110 and heat spreader 120 may be avoided.

In some embodiments, at some thickness dimensions and materials of main layer 114, or at some processing conditions, the quality and handling of main layer 114 may be acceptable such that thermal interface 110 may include only main layer 114, or main layer 114 plus only one of the covering layers 111 and 112. Thus, in some embodiments, one or both of covering layers 111 and 112 may be omitted from thermal interface 110.

In some embodiments, bonding heat spreader 120 to die 130 may be performed with flux. When bonding with flux, as shown in FIG. 1, a first flux 171 may be applied to an area, such as surface 136 of die 130, between die 130 and thermal interface 110 before thermal interface 110 is placed on surface 136. A second flux 172 may be applied to an area, such as covering layer 112, between thermal interface 110 and heat spreader 120 before heat spreader 120 is placed over thermal interface 110. As described above, in some embodiments, one or both of the covering layers 111 and 112 may be omitted from thermal interface 110. In embodiments where covering layer 112 is omitted from thermal interface 110, flux 172 shown in FIG. 1 may be applied directly to surface 102 of main layer 114.

In some embodiments, where flux is used, only one (not both) of flux 171 and flux 172 may be applied to apparatus 100. Thus, in some embodiments, only flux 171 is applied and flux 172 is omitted, or only flux 172 is applied to and flux 171 is omitted. In some embodiments, the use of only one of flux 171 and flux 171 is independent of the inclusion or omission of covering layers 111 and 112. For example, only flux 171 may be used when covering layer 111 is included in or omitted from thermal interface 110. For another example, only flux 172 may be used when covering layer 112 is included in or omitted from thermal interface 110.

In some embodiments, bonding heat spreader 120 to die 130 may be performed in the absence of flux. Thus, in some embodiments, both flux 171 and second flux 172 are omitted from apparatus 100. In some embodiments, the omission of both flux 171 and flux 172 is independent of the inclusion or omission of covering layers 111 and 112. For example, both flux 171 and flux 172 may omitted when both covering layers 111 and 112 are included in thermal interface 110. For another example, both flux 171 and flux 172 may be omitted from thermal interface 110 when only one of the covering layers 111 and 112 is included in thermal interface 110.

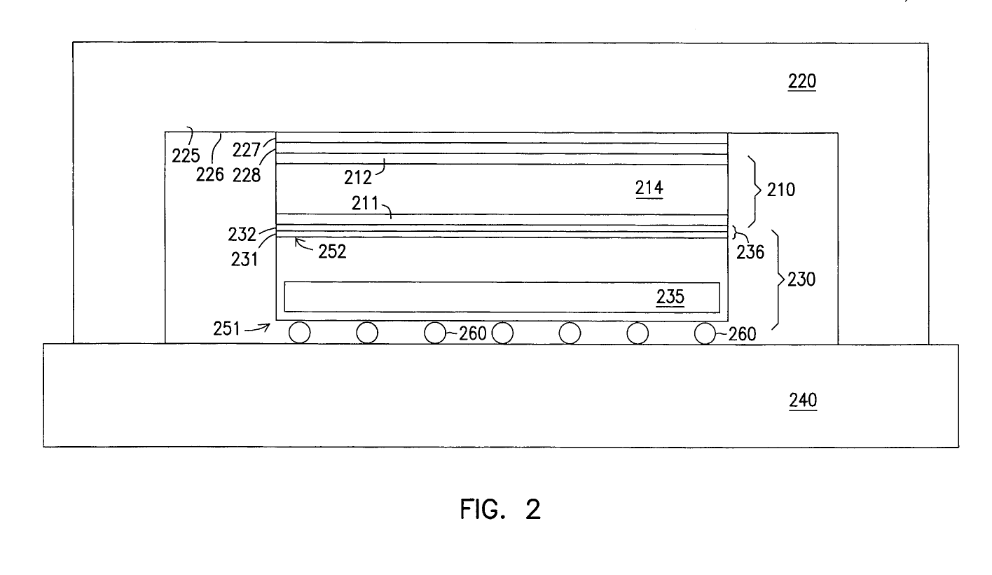

Apparatus 100, after being assembled, may have a structure as shown in FIG. 2.

FIG. 2 shows an apparatus 200 according to an embodiment of the invention.

In some embodiments, apparatus 200 includes an embodiment of apparatus 100 of FIG. 1 after apparatus 100 is assembled together. In FIG. 2, apparatus 200 includes a package substrate 240, and a thermal interface 210 bonded to a heat spreader 220 and a die 230. In some embodiments, package substrate 240 includes an organic substrate.

Heat spreader 220 includes a layer 225, and layers 227 and 228 covering layer 225. FIG. 2 shows layers 227 and 228 covering only a portion of surface 226 of layer 225. In some embodiments, layer 227, layer 228, or both layers 227 and 228 may cover the entire surface 226. In some embodiments, layer 225 may include copper, layer 227 may include nickel, and layer 228 may include gold. Other materials for layers 225, 227, and 228 may be used.

Die 230 includes surfaces 251 and 252, and an integrated circuit 235 located at an active side of die 230. In FIG. 2, the active side refers to the side with surface 251, which has a number of conductive pads 260 to allow transfer of electrical signals to and from integrated circuit 235. Die 230 also includes a backside which is opposite from the active side. In FIG. 2, the backside refers to the side with surface 252. Integrated circuit 235 is closer to surface 251 (on the active side) than to surface 252 (on the backside). In some embodiments, the location of integrated circuit 235 within die 230 may vary.

Die 230 also includes a metallization structure 236 on surface 252 (on the backside) of die 230. Metallization structure 236 includes a stack of layers 231 and 232. Layer 231 may include nickel or an alloy having nickel. Layer 232 may include gold. Metallization structure 236 may include other materials instead of nickel and gold. In some embodiments, metallization structure 236 may include fewer or more than two layers.

Thermal interface 210 includes a main layer 214, a covering layer 211, and a covering layer 212. In some embodiments, thermal interface 210 includes the embodiments of thermal interface 110 of FIG. 1. Thus, before or after being bonded together, the components of thermal interface 210 of FIG. 2 may include the materials and thickness dimensions of thermal interface 110 as described in FIG. 1.

In some embodiments, both covering layer 211 and 212 may be omitted from apparatus 200 such that main layer 214 directly contacts both heat spreader 220 and die 230. In other embodiments, only one of the covering layers 211 and 212 may be omitted from apparatus 200 such that main layer 214 directly contacts either only heat spreader 220 or only die 230.

In FIG. 2, the components of apparatus 200 are shown in exaggerated dimensions for illustration purposes. In some embodiments, the materials of some of the components of apparatus 200 may combine to form a combination of materials having an intermetallic structure. For example, the materials of the components of thermal interface 210 and the materials of at least one of the components of heat spreader 220 and die 230 may combine to form an intermetallic structure of these of materials.

In FIG. 2, thermal interface 210 may be bonded to heat spreader 220 and die 230 with flux or without flux.

In the bonding process with flux, the interface between heat spreader 220 and die 230 (i.e., the interface including thermal interface 210), may be substantially free of voids. Substantially free of voids means that no voids are present, or if any voids are present, the voids are less than about 1% by volume. The void fraction can be determined by any known technique. For example, the void fraction can be determined by the Archimedes method, which determines a known density for a given material. For another example, the void fraction can also be determined by using a scanning acoustic microscope (SAM).

In the bonding process without flux, the interface between heat spreader 220 and die 230 (i.e., the interface including thermal interface 210), is substantially free of an organic flux or an organic flux residue. The term “substantially free” means that, under clean-room conditions that are used during the bonding process, analytical evaluation of apparatus 200 at the level of thermal interface 210 will result in no detectable flux or flux residue, absent a false positive. No detectable flux means that if there were any organic flux present, it would be below detection, and if not below detection, it would be tracked to a contaminant and not to a residue of a process that was used.

In some embodiments, by choosing the materials and the thickness for thermal interface 210 according to the materials and thickness described herein, apparatus 200 may have a relatively low CTE mismatch between heat spreader 220 and die 230.

In some embodiments, apparatus 200 may have a relatively low thermal resistance. The thermal resistance of a package such as apparatus 200 is determined, in part, by thermal junction-to-case resistance (R_{jc}) of the package. The R_{jc} of the package is commonly the measurement of the thermal resistance between a junction within the package (e.g., a top or bottom surface of a die) and a reference point (e.g., a top or bottom of the package). In FIG. 2, for example, the R_{jc} may be the thermal resistance between die 230 and a reference point above it, such as a point above heat spreader 220. The R_{jc} measurement of apparatus 200 may be taken at various locations such as the center and a corner of apparatus 200. Thus, apparatus 200 may have a center R_{jc} measurement and a corner R_{jc} measurement. By choosing the materials and the thickness of thermal interface 210 based on the materials and thickness described herein, apparatus 200 may have a relatively low center R_{jc} and low corner R_{jc}. Therefore, dissipating heat from die 230 may be more effective.

In some embodiments, apparatus 200 has a center R_{jc} of about 0.071° C/W. In other embodiments, apparatus 200 has a center R_{jc} of about 0.08° C/W. In some other embodiments, apparatus 200 has a center R_{jc} between about 0.071° C/W and about 0.08° C/W. In some embodiments, apparatus 200 has a corner R_{jc} of about 0.0054° C/W. In other embodiments, apparatus 200 has a corner R_{jc} of about 0.042° C/W. In some other embodiments, apparatus 200 has a corner R_{jc} between about 0.0054° C/W and about 0.042° C/W.

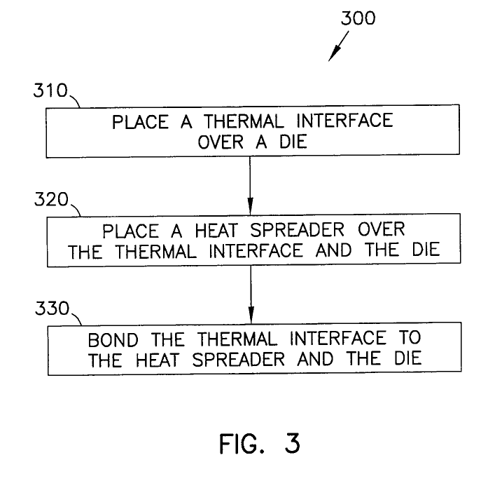

FIG. 3 is a flowchart showing a method according to an embodiment of the invention. Method 300 is shown in schematic form in which some activities may be described but are omitted from FIG. 3 for clarity. Method 300 may be used in the embodiments represented by FIG. 1 and FIG. 2.

Activity 310 of method 300 places a thermal interface over a die. The thermal interface and the die in method 300 may include embodiments of thermal interfaces and the dice described in FIG. 1 and FIG. 2. Thus, in some embodiments, the thermal interface and the die in method 300 may have the materials and thickness dimensions of thermal interface 110, thermal interface 210, die 130, and die 230 of FIG. 1 and FIG. 2.

Activity 320 of method 300 places a heat spreader over the thermal interface and the die. The heat spreader may include embodiments of heat spreader 120 of FIG. 1 and heat spreader 220 of FIG. 2.

Activity 330 of method 300 bonds the thermal interface to the heat spreader and the die in a bonding process.

In some embodiments, method 300 bonds the thermal interface to the heat spreader and the die with flux or without flux.

In some embodiments, where flux is used, the flux may be applied to both the area between the die and the thermal interface and the area between the thermal interface and the heat spreader. For example, a first flux may be applied to a surface of the die before the thermal interface is placed over the surface of the die; a second flux may be applied to a surface of the thermal interface before the heat spreader is placed over both the thermal interface and the die. In this example, the first flux contacts the die and a first surface of the thermal interface after the thermal interface is placed over the die; the second flux contacts a second surface of the thermal interface and the heat spreader after the heat spreader is place over both the thermal interface and the die. In other embodiments, where flux is used, the flux may be applied to only the area between the die and the thermal interface or to only the area between the thermal interface and the heat spreader.

In embodiments where flux is used, the bonding in activity 330 may be performed in a vacuum oven or in an oven with a pressure inside the oven being lower than the pressure outside the oven. For example, the bonding in activity 330 may be performed in an oven with a pressure inside the oven being lower than the atmospheric pressure. It is understood that the average atmospheric pressure is one atmosphere (1 amt or 760 Torr). In some embodiments, the bonding in activity 330 may be performed in an oven in which the pressure in the oven is about 50 Torr to about 100 Torr. In some embodiments, the lower than atmospheric pressure may be applied to the oven for only a fraction of the time of the bonding process in activity 330. In other embodiments, the lower than atmospheric pressure may be applied to the oven for the entire time of the bonding process in activity 330. Causing the pressure inside the oven to be lower than the atmospheric pressure may enable suction or extraction of volatiles and chemical reaction products of the flux or flux residue from the interface between the die and the heat spreader and the thermal interface (i.e., the interface including thermal interface). The suction may reduce voiding level or voids in the interface between the die and the heat spreader after the bonding process is completed.

In some embodiments, where flux is absent, the bonding in activity 330 may be performed in an oxygen-free environment (e.g., a nitrogen environment). In some embodiments, where flux is absent, the bonding in activity 330 may include removing oxidation or surface oxide from the surfaces of the thermal interface, the heat spreader, the die, or any combination of these surfaces. In some embodiments, a material may be introduced into the oven to remove the surface oxide. The material used to remove the surface oxide may be a gas or a plasma. For example, fluorine gas or plasma may be used to remove the surface oxide. Other materials besides fluorine may be used. In some embodiments, where flux is absent, the bonding in activity 330 may be performed in an oven in which the pressure inside the oven may be lower than the atmospheric pressure. A lower than atmospheric pressure inside the oven may reduce voids in the interface between the die and the heat spreader after the bonding process is completed.

Bonding the thermal interface to the heat spreader and the die may be performed at a process temperature. In embodiments where the thermal interface includes indium, a relatively low process temperature may be used. In some embodiments, the process temperature is about the melting point or the eutectic point of the materials of the thermal interface. In other embodiments, the process temperature is either about the melting point or about the eutectic point of the materials of the thermal interface plus an increased temperature range. In some embodiments, the increased temperature range is about (5X+1)° C. to about 5Y° C., where X>0, and Y=X+1. For example, the process temperature is either about the melting point or about the eutectic point of the materials of the thermal interface plus an increased temperature range of 1° C. to 5° C. (X=0), 6° C. to 10° C. (X=1,), or 11° C. to 15° C. (X=2). In some embodiments, the processing temperature in activity 330 is between about 143° C. and about 180° C.

In some embodiments, the bonding process in activity 330 may be performed for about two minutes to about one and one-half hours. In some embodiments, method 300 may use a device to clip the heat spreader, the thermal interface, and the die together with a clip force to improve bonding.

In method 300, some embodiments or examples in one of the activities 310, 320, and 330 may be included in, or substituted for, those of other activities.

FIG. 1 through FIG. 3 describe some materials, thickness dimensions, process order, and process parameters such as time, temperature and pressure, only for examples. Other materials, thickness dimensions, process order, and process parameters may be used. However, for some embodiments, the materials, thickness dimensions, process order, and process parameters described herein may be more effective than the other materials, thickness dimensions, process order, and process parameters in one or more of the following: reducing CTE mismatch between the die and the heat spreader, reducing thermal resistance R_{jc}, enhancing wetting during the bonding, improving bond quality of the interface between the die and the heat spreader, reducing voiding level in the interface between the die and the heat spreader, improving the handling of the thermal interface, enabling low process temperature for bonding, and reducing cost.

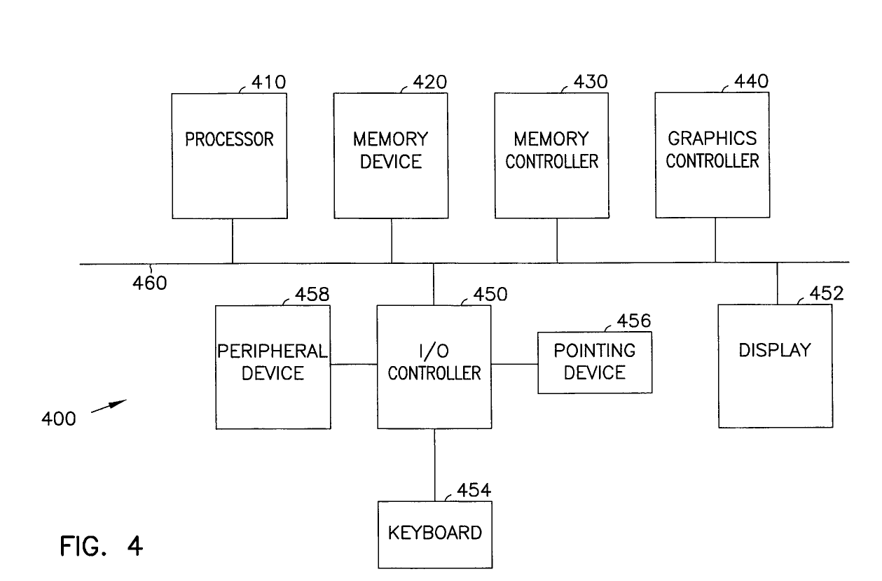

FIG. 4 shows a computer system according to an embodiment of the invention. System 400 includes a processor 410, a memory device 420, a memory controller 430, a graphics controller 440, an input and output (I/O) controller 450, a display 452, a keyboard 454, a pointing device 456, a peripheral device 458, and a bus 460.

Processor 410 may be a general purpose processor or an application specific integrated circuit (ASIC). I/O controller 450 may include a communication module for wired or wireless communication. Memory device 420 may be a dynamic random access memory (DRAM) device, a static random access memory (SRAM) device, a flash memory device, or a combination of these memory devices. Thus, in some embodiments, memory device 420 in system 400 does not have to include a DRAM device.

One or more of the components shown in system 400 may be included in one or more integrated circuit packages. For example, processor 410, or memory device 420, or at least a portion of I/O controller 450, or a combination of these components may be included in an integrated circuit package that includes at least one embodiment of an article or apparatus described in FIG. 1 through FIG. 3.

Thus, one or more or the components shown in system 400 may include at least one or a combination of a die, a heat spreader, and a thermal interface such as those described in FIG. 1 through FIG. 3.

System 400 may include computers (e.g., desktops, laptops, hand-helds, servers, Web appliances, routers, etc.), wireless communication devices (e.g., cellular phones, cordless phones, pagers, personal digital assistants, etc.), computer-related peripherals (e.g., printers, scanners, monitors, etc.), entertainment devices (e.g., televisions, radios, stereos, tape and compact disc players, video cassette recorders, camcorders, digital cameras, MP3 (Motion Picture Experts Group, Audio Layer 3) players, video games, watches, etc.), and the like.

The above description and the drawings illustrate some specific embodiments of the invention sufficiently to enable those skilled in the art to practice the embodiments of the invention. Other embodiments may incorporate structural, logical, electrical, process, and other changes. In the drawings, like features or like numerals describe substantially similar features throughout the several views. Examples merely typify possible variations. Portions and features of some embodiments may be included in, or substituted for, those of others. Many other embodiments will be apparent to those of skill in the art upon reading and understanding the above description. Therefore, the scope of various embodiments is determined by the appended claims, along with the full range of equivalents to which such claims are entitled.

The Abstract is provided to comply with 37 C.F.R. §1.72(b) requiring an abstract that will allow the reader to quickly ascertain the nature and gist of the technical disclosure. The Abstract is submitted with the understanding that it will not be used to interpret or limit the scope or meaning of the claims.

What is claimed is:

1. An apparatus comprising:
a die;
a heat spreader; and
a thermal interface bonded to the die and the heat spreader, wherein the thermal interface includes indium and an additional material.

2. The apparatus of claim 1, wherein the additional material of the thermal interface includes silver alloyed with the indium.

3. The apparatus of claim 2, wherein the thermal interface has a thickness of about 50 μm to about 100 μm, and wherein the die has a thickness of about 50 μm to about 300 μm.

4. The apparatus of claim 1, wherein the thermal interface has a presence of flux residue.

5. The apparatus of claim 4, wherein the thermal interface has a presence of voids of less than 1% by volume.

6. The apparatus of claim 1, wherein the thermal interface is substantially free of flux residue.

7. The apparatus of claim 1, wherein the die includes a gold layer directly contacting the thermal interface, and wherein the heat spreader includes a gold layer directly contacting the thermal interface.

8. The apparatus of claim 7, further comprising a substrate coupled to the die and the heat spreader.

9. The apparatus of claim 1, wherein the die, the spreader, and the thermal interface have a center junction-to-case resistance (R_{jc}) of about 0.071° C/W.

10. The apparatus of claim 1, wherein the die, the spreader, and the thermal interface have a center junction-to-case resistance (R_{jc}) of about 0.08° C/W.

11. The apparatus of claim 1, wherein the die, the spreader, and the thermal interface have a corner junction-to-case resistance (R_{jc}) of about 0.0054° C/W.

12. The apparatus of claim 1, wherein the die, the spreader, and the thermal interface have a corner junction-to-case resistance (R_{jc}) of about 0.042° C/W.

13. An apparatus comprising:
a die;
a heat spreader; and
a thermal interface bonded to the die and the heat spreader, wherein the thermal interface includes only a single material.

14. The apparatus of claim 13, wherein the single material includes indium.

15. The apparatus of claim 13, wherein the die, the spreader, and the thermal interface have a center junction-to-case resistance (R_{jc}) between about 0.071° C/W and about 0.08° C/W.

16. The apparatus of claim 13, wherein the die, the spreader, and the thermal interface have a corner junction-to-case resistance (R_{jc}) between about 0.0054° C/W and about 0.042° C/W.

17. The apparatus of claim 13, wherein the thermal interface directly contacts the die and the heat spreader.

18. A system comprising:
a die;
a heat spreader;
a thermal interface bonded to the die and the heat spreader, wherein the thermal interface includes indium and an additional material; and
a random access memory device coupled to the die.

19. The system of claim 18, wherein the additional material of the thermal interface and the indium form a eutectic alloy.

20. The system of claim 19, wherein the die, the heat spreader, and the thermal interface reside in a first integrated circuit package, and wherein the random access memory device resides in a second integrated circuit package.
